(19) United States
(12) Patent Application Publication
(10) Pub. No.: US 2006/0065943 A1
(43) Pub. Date: Mar. 30, 2006

(54) Thin film alternating current solid-state lighting

(75) Inventor: E. Steven Hill, Castle Rock, CO (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: GROUP IV SEMICONDUCTOR INC., Ottawa (CA)

(21) Appl. No.: 11/229,220

(22) Filed: Sep. 16, 2005

Related U.S. Application Data
(60) Provisional application No. 60/610,203, filed on Sep. 16, 2004.

(51) Int. Cl. H01L 31/00

(52) U.S. Cl. 257/442

(57) ABSTRACT

Group IV semiconductor nanocrystal doped with rare earths or other light emitting metal to form alternating current solid-state devices that can be designed to operate at a variety of voltages including line voltages. The semiconductor nanocrystals are preferably silicon, silicon carbide, germanium or germanium carbide, and the electric luminescent device may have an upper and lower thin coat of a semiconductor nanocrystal glass material in turn connected to alternating current electrodes. The present invention enables one to fabricate a solid-state light that can use standard fixtures, e.g. Edison type, and standard AC voltages and frequencies for use in houses and businesses without refurbishing the installed lighting fixtures.

### CROSS-REFERENCE TO RELATED APPLICATIONS

The present invention claims priority from U.S. Patent No. 60/610,203 filed Sep. 16, 2004, which is incorporated herein by reference.

### FIELD OF THE INVENTION

The invention relates to solid-state lighting devices, and in particular to thin film solid state lighting devices powered by alternating current.

### BACKGROUND OF THE INVENTION

The next generation of solid-state lighting is seeking to provide advances in brightness, efficiency, colour, purity, packaging, scalability, reliability and reduced costs. One such technology is thin film electroluminescence (TFEL) inorganic phosphors. TFEL devices can provide high brightness, outstanding durability and excellent reliability. Current inorganic TFEL phosphors are composed of group II-VI semiconductor hosts, such as zinc sulfide and strontium sulfide, which provide hot carriers (greater than two electron volts) that excite luminescent centres, such as manganese, cerium, and copper.

Sufficient hot carrier generation requires a high field strength exceeding the break down field of the phosphor thin film. An alternating current biased dielectric-phosphor-dielectric layered structure enables reliable high field operation by current limiting of the electrical breakdown of the phosphor layer. Generally these dielectric layers are thin film dielectric layers, which are applied by sputtering or other suitable method. As such, the thickness of the dielectric layers is generally limited. The thinness of the dielectric layer limits the voltage which can be applied and further the reliability of the TFEL.

An object of the present invention is to overcome the shortcomings of the prior art by providing a solid-state lighting device including a rare earth doped, group-IV semiconductor nanocrystal material driven by an alternating current power source by direct tunnelling without the need for two dielectric barrier layers on either side.

### SUMMARY OF THE INVENTION

Embodiments of the invention provide solid state lighting devices featuring a doped group IV semiconductor nanocrystal material driven by an alternating current as a power source, preferably operable at line voltages of 110/220 V. The present invention relies on the isolation of group IV semiconductor nanocrystals, such as silicon, silicon carbide, germanium or germanium carbide, doped with an emitting rare earth or other metal, and subjection to an alternating current to provide electroluminescence. Group IV-based electroluminescent semiconductor nanocrystals have the advantage of high brightness red, green, blue and/or white emission. The group IV-based semiconductor nanocrystals are also extremely rugged, which allows them to be electrically driven at high input powers without significant semiconductor nanocrystal degradation. Furthermore, group IV-based semiconductor nanocrystals are stable up to temperatures as high as 1100° C., which provides compatibility of the group IV semiconductor nanocrystals with harsh electroluminescent device fabrication techniques, e.g. screen-printing a high performance and thick film dielectric layer requires a high sintering temperature of >800° C. Moreover, the ruggedness of the group IV semiconductor nanocrystals enables high temperatures and reactive chemicals to be utilized in device fabrication.

According to one broad aspect, the invention provides an alternating current solid-state device comprising: a visible light emitting semiconductor nanocrystal structure comprising a first dielectric film having first and second surfaces, and containing Group IV semiconductor nanocrystals doped with at least a first light emitting element; and a contact arrangement through which an alternating current can be applied across said first surface and said second surface. In some embodiments, the contact arrangement comprises a conductive substrate on one side of the film, and a transparent electrode on another side of the film.

In some embodiments, the contact arrangement further comprises an AC is a socket arrangement.

In some embodiments, the AC socket arrangement comprises an Edison type fixture.

In some embodiments, the AC socket arrangement comprises a fluorescent type fixture.

In some embodiments, the device further comprises a second dielectric film coating the first film, the second film containing Group IV semiconductor nanocrystals doped with a light-emitting element so as to emit light of a different colour than the first film.

In some embodiments, said dielectric layers comprise materials selected from the group consisting of silicon dioxide, silicon nitride, silicon oxide, aluminum nitride, aluminum tin oxide, aluminium oxide, and silicon oxinitride.

In some embodiments, said contact arrangement comprises a first electrode applied to the first surface of first film and a second electrode applied to the second surface of the first.

In some embodiments, at least one of said electrodes is transparent.

In some embodiments, adjacent devices have electroluminescent semiconductor nanocrystal layers doped with different dopants whereby said adjacent electroluminescent devices emit different colours.

In some embodiments, a plurality of adjacent solid-state devices each arranged to tailor light distribution.

According to another broad aspect, the invention provides an alternating current solid-state device comprising: a conductive core; a dielectric film comprising Group IV semiconductor nanocrystals doped with a visible light emitting element and arranged to at least partially surround the conductive core; a transparent electrode at least partially surrounding the dielectric film; wherein the nanocrystals can be energized with an alternating current applied across the core and the transparent electrode.

In some embodiments, the core is solid cylindrical in shape, and the glass and transparent electrodes are hollow and cylindrical in shape.

In some embodiments, the device is adapted to operate at a line voltage of at least 110-120V AC without any down conversion or rectification.

In some embodiments, the device is adapted to operate at a line voltage of at least 220-240V AC without any down conversion or rectification.

In some embodiments, the light-emitting element is a rare earth element.

In some embodiments, the light-emitting element is selected from a group consisting of: Pr, Ev, Tb, Er, and Tm.

### BRIEF DESCRIPTION OF THE DRAWINGS

FIG. 1 is a cross-sectional view of an alternating current electroluminescent solid-state device provided by an embodiment of the present invention;

FIG. 2 is a cross-sectional view of an alternate embodiment of an alternating current electroluminescent solid-state device of the present invention;

FIGS. 3A to 3C are perspective views of the present invention utilizing Edison-style sockets;

FIG. 4 is a partially sectioned isometric view of a lighting element provided by an embodiment of the invention to fit fluorescent socket; and

FIG. 5 is a partially sectioned isometric view of a lighting element featuring a cylindrical film.

### DETAILED DESCRIPTION OF THE PREFERRED EMBODIMENTS

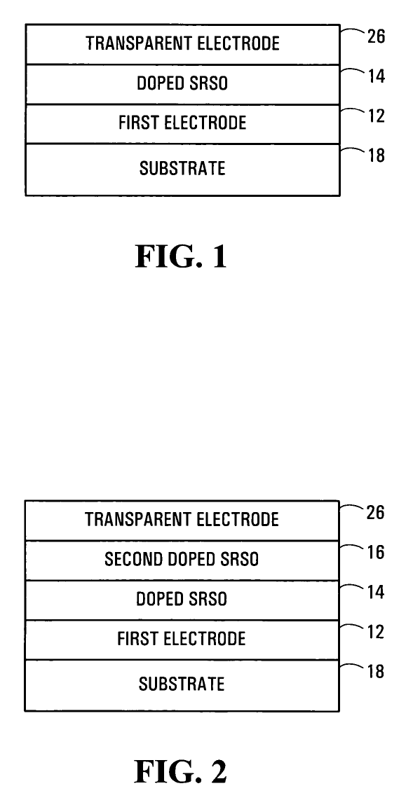

With reference to FIG. 1, an embodiment of present invention includes an electroluminescent solid-state device 10, which incorporates a first electrode 12 coated with a thin film semiconductor nanocrystal dielectric layer 14, which contains one or a combination of rare earth ions and group IV semiconductor nanocrystals distributed substantially evenly in therein, e.g. doped silicon-rich silicon oxide (SRSO). The upper surface of the semiconductor nanocrystal layer 14 is covered, at least in part, by a transparent electrode 26, e.g. an indium tin oxide (ITO) layer. Other suitable materials for transparent electrodes may alternatively be employed.

The structures shown in FIG. 1 and the figures that follow show adjacent layers in contact with each other without intervening layers; however, additional layers can be utilized to the extent they do not interfere with the recited layers. Therefore the terms coating and in contact do not exclude the possibility of additional intervening but non-interfering layers.

For example, the illustrated example also includes a substrate 18 that may or may not be conductive. If the substrate 18 is conductive, it may not be necessary to include a separate electrode layer 12; however, in the illustrated embodiment, the electrode layer 12 is a ground electrode, preferably p⁺ silicon.

Suitable semiconductor nanocrystal dielectrics include, but are not limited to, silicon dioxide, silicon nitride, silicon oxinitride, aluminum nitride, aluminum tin oxide and aluminum oxide, which can be deposited by a variety of different methods, such as plasma enhancement chemical vapour deposition (PECVD) and other suitable methods.

The semiconductor nanocrystal layer is a group IV semiconductor material doped with a light emitting rare earth element, transition metal or other metal. The preferred group IV semiconductors include silicon, silicon carbide, germanium, and germanium carbide, which can be doped with a variety of elements, such as praseodymium (Pr), europium (Eu), terbium (Tb), erbium (Er), and thulium (Tm).

Any production method, which forms nanocrystal semiconductors, can be used to apply the semiconductor nanocrystal layer. Suitable techniques include molecular beam epitaxy, metalo-organic chemical vapor deposition, chemical vapor deposition, plasma enhanced chemical vapor deposition, vapor phase epitaxy, plasma enhanced chemical deposition, sol-gel, sputtering, and evaporation.

Applicant's co-pending applications: U.S. Patent Publication No. 2004/0149353 entitled “Doped Semiconductor Powder and Preparation Thereof”, filed Jan. 22, 2004, U.S. Patent Publication No. 2004/0214362 entitled “Doped Semiconductor Nanocrystal Layers and Preparation Thereof”, filed Jan. 22, 2004, PCT Patent Publication No. WO 2004/066346 entitled “Doped Semiconductor Nanocrystal Layers or Doped Semiconductor Powders and Photonic Devices Employing Such Layers or Powders”, filed Jan. 22, 2004, and PCT Patent Application No. PCT/CA2004/000075 entitled “Doped Semiconductor Nanocrystal Layers and Preparation Thereof”, filed Jan. 22, 2004, which are incorporated herein by reference, teach doped semiconductor powders and layers doped with rare-earth elements and processes and preparations for making these layers and powders.

Preferably, the semiconductor nanocrystal layer 14, which is used in the device of FIG. 1 and in the other embodiments described below, is implemented in accordance with any of the described materials or processes of these applications all of which are hereby incorporated by reference in their entirety. It is also noted that if a PECVD is used to produce the rare-earth doped silicon nanocrystals, a rare-earth doped silicon carbide nanocrystal with a concentration of approximately 1 to 20 atomic percent of carbon, preferably 5 to 20 atomic percent, may result, and this is also acceptable for use in any of the embodiments described herein.

In an exemplary implementation, the thickness of semiconductor nanocrystal layer 14 is about 200 nm; however, an increased film thickness would permit application of higher applied voltages. In practice, the effective thickness of the semiconductor nanocrystal layer 14 is limited by the method of application. Generally the semiconductor nanocrystal layer 14 is limited to a thickness of about 200-1000 nm; however, by decreasing the film thickness the drive voltage can be reduced, e.g. a 24 volts maximum might exist for some implementations by decreasing the film thickness to 30 nanometers.

The desired thickness of the semiconductor nanocrystal layer 14 is from about 0.02 to 1 micron with 0.2 to 0.5 microns being preferred. For the rare earth or metal dopant to be strongly optically active in the dielectric, which has the group IV semiconductor nanocrystals, the dopant, should be incorporated in the dielectric oxide. This permits the light-emitting element to sit in an optically active site, which promotes visible light emission. The thickness of the semiconductor nanocrystal layer 14 will have an effect on the applied field across the doped semiconductor nanocrystals embedded therein. As an example, if there is only one doped semiconductor nanocrystal film being used and the applied field is 120 volts AC (60 Hz), the film thickness should be approximately 250 nanometers. If two doped semiconductor nanocrystal layers are being used, each layer should be approximately 125 nanometers thick, so that the overall thickness of the stacked layers would be approximately 250 nanometers for the 120 volts AC.

The rare earth dopant might, for example, be Tm for a blue emission, Pr or Eu for a red emission and Er or Tb for a green emission. These can be added to the dielectric by either in situ methods or post growth doping using ion implantation or diffusion. Preferably, the concentration of the dopant is relatively high from less than 0.1% up to about 10 atomic percent or higher. The dopant concentration can be increased until the emission stops. Generally, the preferred concentration will be 0.1 to 15 atomic percent of one or more rare earth elements dispersed on or near the surface of the semiconductor nano-particles, and distributed substantially equally through the thickness of the first group IV oxide layer. A concentration of 0.5 to 15 atomic percent is more preferred, and 0.5 to 10 atomic percent is most preferred.

Referring now to FIG. 2, another solid-state light emitting device provided by an embodiment of the present invention is illustrate. The device of FIG. 2 is similar to that of FIG. 1, with the addition of a second group IV semiconductor nanocrystal layer 16 having different rare earth composition than the first dielectric layer 14. In this case, the transparent electrode layer 26 is applied on an outer surface of the second dielectric group IV semiconductor nanocrystals layer 16. By including two separate layers of group IV semiconductor nanocrystal material, more flexibility and control over the light colour produced by the device can be achieved. For example, different dopants might be used such that each layer emits a different colour. Additional group IV semiconductor nanocrystal layers 16 can be added with different dopants or groups of dopants to adjust the colour of emitted light even further. Dielectric layers can be placed in between the group IV semiconductor nanocrystal layers 16.

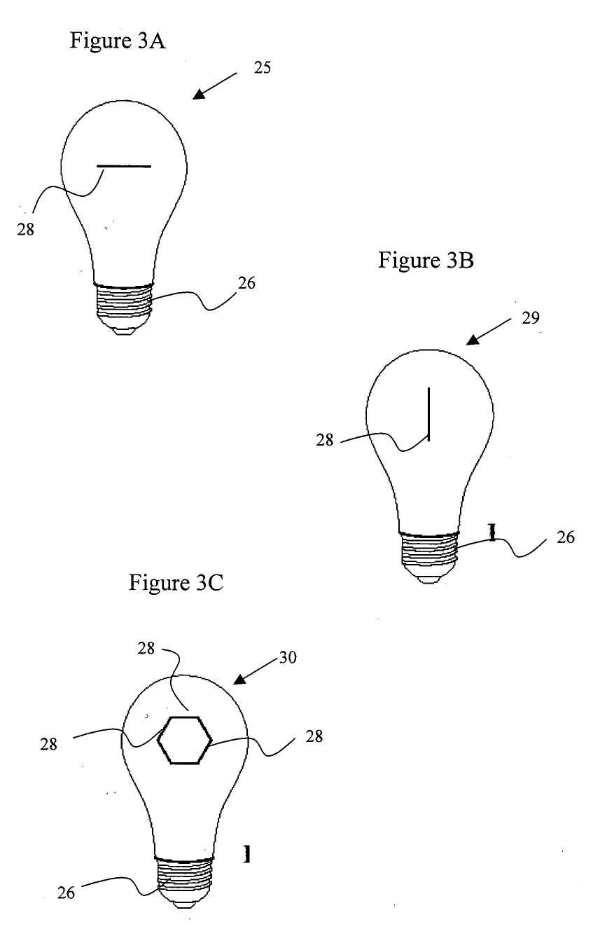

Referring now to FIG. 3A, a lighting fixture 25 provided by an embodiment of the invention consists of an Edison type fixture 27 with a socket contact structure, in which the group IV semiconductor nanocrystal structure 28 is in a horizontal position. A similar lighting fixture device 29 is illustrated in FIG. 3B in which the group IV semiconductor nanocrystal structure 28 is in a vertical position. In another embodiment of a light fixture 30, the group IV semiconductor nanocrystal structure is made from several of the nanostructure devices 28. An example is shown in FIG. 3C where a six-sided arrangement of group IV semiconductor nanocrystal structures 28 is employed to give a more hemispherical Lambertian light distribution. More generally, one or more group IV semiconductor nanocrystal structures can be arranged to tailor the light distribution, e.g. the edges of 3, 4, 5, etc semiconductor nanocrystal structures can be connected forming any desired geometrical shape, e.g. triangle, square, pentagon, to distribute the light accordingly. Alternative socket contact structures can be used, including the bayonet structure used in the UK or other used structures, such as GU10 and MR16.

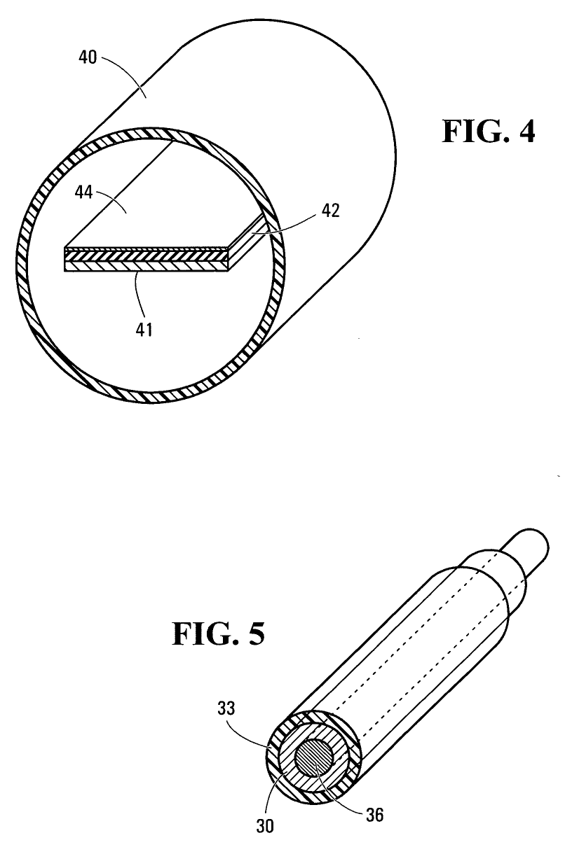

In another embodiment, a fluorescent fixture type bulb that could be placed into a FT10 lighting fixture is provided, which includes fluorescent socket contact structures, as is well known in the art. FIG. 4 illustrates a tubular bulb 40 with a conductive substrate 41 having a doped group IV semiconductor nanocrystal structure in the form of a long film 42 with a transparent top electrode 44, such as ITO, to spread the current the length of the tubular bulb 40.

FIG. 5 illustrates a doped group IV semiconductor nanocrystal film provided in the form of a cylindrical or semi-circular structure 30, which is partially or totally surrounded by an outer transparent electrode 33, which is cylindrical or at least partially cylindrical core electrode. A core electrode 36 is at least partially surrounded by the nanocrystal film structure 30. Preferably, the core electrode 36 has a solid cylindrical structure totally surrounded by the nanocrystal film structure 30. The outer electrode 33 is a transparent electrode, such as ITO, and the inner core electrode 36 can be any suitable material, such as silver and/or platinum (AgPt).

According to embodiments of the invention, each of the arrangements described are driveable by an AC power supply. In other words, solid-state AC-drive lighting devices are provided. Preferably, an AC-power supply is connected directly to the various devices at line voltage of for example 110 V (60 Hz) or 220 V (50 Hz) AC, without the requirement to downconvert to a lower voltage, or to convert to DC as is the case with conventional LEDs. The standard voltages for North America and Japan are 110-120 volts AC @ 60 Hz, but in most of the rest of the world, including Europe and China, the standard voltages are 220-240 volts AC @ 50 Hz. Accordingly, the combined thickness of the various semiconductor nanocrystal layers must be adjusted to suite the available voltage and frequency.

The resulting structure is a Metal Oxide Semiconductor (MOS) structure that is operated by a field and tunnelling conduction rather than by a “standard” semiconductor that has either an excess of holes or electrons and thus can conduct current only in one direction, i.e. a diode.

To reiterate, the nature of having the semiconductor nanocrystals in the dielectric film results in a field effect that drives the current through the dielectric film. The nanocrystals prevent having an avalanche breakdown, which would destroy the emitter since the current would increase exponentially and short out. Since this is a field effect in a Metal Oxide Semiconductor (MOS) we do not have the problem of having electrical conduction in only one direction as in a normal semiconductor being determined by the type of semiconductor of P or N type.

More generally, the devices can be designed for a variety of voltages, and are not generally limited to a single diode drop like conventional LEDs. By increasing the layer thickness, higher field voltages can be applied. The operating range in some implementations is in the range of 1×10³ to 5×10⁵ volts per centimetre field strength.

Furthermore, the devices can be designed to operate on a variety of alternating voltages, including main power frequencies.

Numerous modifications and variations of the present invention are possible in light of the above teachings. It is therefore to be understood that within the scope of the appended claims, the invention may be practiced otherwise than as specifically described herein.

We claim:

1. An alternating current solid-state device comprising:
a visible light emitting semiconductor nanocrystal structure comprising a first dielectric film having first and second surfaces, and containing Group IV semiconductor nanocrystals doped with at least a first light emitting element; and
a contact arrangement through which an alternating current can be applied across said first surface and said second surface.

2. The device of claim 1, wherein the contact arrangement comprises a conductive substrate electrically connected to one side of the first dielectric film, and a transparent electrode electrically connected to another side of the first dielectric film.

3. The device of claim 2, wherein the contact arrangement includes a socket arrangement.

4. The device of claim 3, wherein the AC socket arrangement comprises an Edison type fixture.

5. The device of claim 3, wherein the AC socket arrangement comprises a fluorescent type fixture.

6. The device of claim 1, wherein the semiconductor nanocrystal structure further comprises a second dielectric film, the second dielectric film containing Group IV semiconductor nanocrystals doped with a second light emitting element so as to emit light of a different colour than the first dielectric film.

7. The device of claim 1, wherein said first dielectric film comprises one or more materials selected from a group consisting of silicon dioxide, silicon nitride, silicon oxide, aluminum nitride, aluminum tin oxide, aluminum oxide and silicon oxinitride.

8. The device of claim 1, wherein said contact arrangement comprises a first electrode applied to the first surface of the first dielectric film and a second electrode applied to the second surface of the first dielectric film.

9. The device of claim 8, wherein at least one of said first and second electrodes is transparent.

10. The device of claim 1, further comprising additional visible light emitting semiconductor nanocrystal structures; wherein each visible light emitting semiconductor nanocrystal structure has semiconductor nanocrystal layers doped with different dopants for emitting different colours.

11. The device of claim 1, further comprising a plurality of additional visible light emitting semiconductor nanocrystal structures forming a geometrical structure and arranged to shape a direction and an intensity distribution of emitted light.

12. The device according to claim 1, wherein the first dielectric film is cylindrical in shape; and wherein the contact arrangement includes a conductive core disposed inside the first dielectric film, and a transparent electrode at least partially wrapped around the outside of the first dielectric film.

13. The device of claim 12, wherein the core is solid and cylindrical in shape, and wherein the glass and transparent electrodes are hollow and cylindrical in shape.

14. The device of claim 1, wherein the visible light emitting semiconductor nanocrystal structure has a thickness enabling the device to operate at a line voltage of at least 110-120V AC without any down conversion or rectification.

15. The device of claim 1, wherein the visible light emitting semiconductor nanocrystal structure has a thickness enabling the device to operate at a line voltage of at least 220-240V AC without any down conversion or rectification.

16. The device of claim 1, wherein the light-emitting element comprises one or more rare earth elements.

17. The device of claim 16, wherein the light-emitting element comprises one or more elements selected from the group consisting of: Pr, Ev, Tb, Er, and Tm.

18. The device of claim 16, wherein the one or more rare earth elements are in a concentration of 0.5 to 15 atomic percent.

19. The device of claim 16, wherein the one or more rare earth elements are dispersed on or near the surface of the semiconductor nano-particles, and distributed substantially equally through the first dielectric film.

20. The device of claim 1, wherein the first dielectric film is also doped with carbon in a concentration of from 1 to 20 atomic percent.
